(19) United States
(12) Patent Application Publication
(10) Pub. No.: US 2025/0241003 A1
(43) Pub. Date: Jul. 24, 2025

(54) MOSFET TRANSISTOR

(71) Applicant: STMicroelectronics International N.V., Geneva (CH)

(72) Inventors: Bernadette Gros, Pourcieux (FR); Christian Rivero, Peynier (FR)

(21) Appl. No.: 18/989,455

(22) Filed: Dec. 20, 2024

(30) Foreign Application Priority Data
Jan. 18, 2024 (FR) 2400490

(51) Int. Cl. H10D 30/63; H10D 30/01; H10D 30/60; H10D 86/00

(52) U.S. Cl. CPC H10D 30/637; H10D 30/022; H10D 30/601; H10D 86/201

(57) ABSTRACT

The present description concerns a transistor comprising a channel region extending in a first direction between a drain region and a source region of a semiconductor layer and a gate structure topping the channel-forming region and comprising a gate insulator topped with a gate region; the channel-forming region comprising a first epitaxial channel region having a first length in the first direction, and a second channel region in the semiconductor layer, the first channel region being between the second channel region and the gate structure; and the gate insulator comprising first portions having a first thickness on either side of the first channel region, and a second portion of a second thickness on the first channel region, the second thickness being smaller than the first thickn

### CROSS-REFERENCE TO RELATED APPLICATIONS

This application claims priority to French Application No. 2400490, filed on Jan. 18, 2024, which application is hereby incorporated herein by reference.

### TECHNICAL FIELD

The present disclosure generally concerns electronic components and more particularly field-effect transistors of MOSFET (Metal Oxide Semiconductor Field Effect Transistor) type.

### BACKGROUND

MOSFET-type transistors are field-effect transistors comprising an electrically-conductive gate, which is electrically insulated from a semiconductor substrate by a dielectric layer called gate insulator.

Various MOSFET transistor designs have already been provided.

It would be desirable to at least partly overcome certain disadvantages of known MOSFET transistor designs.

The improvement of the electrical performance of MOSFET transistors, for example for applications in radio frequency (RF) signal switching, advanced analog, embedded non-volatile memories.

### SUMMARY

An embodiment overcomes all or part of the disadvantages of known MOSFET transistors.

An embodiment provides a transistor comprising a drain region and a source region in a semiconductor layer, a channel-forming region extending in a first direction between the drain region and the source region, and a gate structure topping the channel-forming region and comprising a gate insulator topped with a gate region insulated from said channel-forming region by said gate insulator; the channel-forming region comprising a first channel region having a first length in the first direction and being an epitaxial region, and a second channel region in the semiconductor layer, the first channel region being between the second channel region and the gate structure; and the gate insulator comprising first portions having a first thickness on either side of the first channel region, and a second portion of a second thickness on the first channel region, the second thickness being smaller than the first thickness.

According to an embodiment, the second portion is positioned between the first portions in the first direction.

According to an embodiment, the transistor further comprises a lightly-doped drain region in the semiconductor layer, between the second channel region and each of the drain and source regions.

An embodiment provides a method of manufacturing a transistor, the method comprising: forming a first layer of insulator having a third thickness on a semiconductor layer; forming an opening in the first insulator layer, said opening having a first length in a first direction; forming, by epitaxy in the opening, a first channel region of a channel-forming region; forming a second insulator layer having a second thickness on at least the first channel region; the portions of the first insulator layer that remain on either side of the opening forming first portions of a gate insulator, said first portions having a first thickness greater than or equal to the third thickness, and greater than the second thickness, and the portion of the second insulator layer topping the first channel region forming a second portion of the gate insulator; forming a gate region on the gate insulator; and forming a drain region and a source region in the semiconductor layer, a second channel region of the channel-forming region extending in the first direction between the drain region and the source region.

According to an embodiment, the method further comprises forming, in the semiconductor layer, a lightly-doped drain region between the second channel region and each of the drain and source regions.

According to an embodiment, forming the opening comprises etching the first insulator layer throughout the third thickness and along the first length in the first direction, the etching stopping at the semiconductor layer, the etching being, for example, a wet etching.

According to an embodiment, the first thickness is substantially equal to the third thickness.

The following embodiments can apply to the transistor and to the transistor manufacturing method.

According to an embodiment, the first thickness is in the range from 5 to 10 nm, for example from 6 to 9 nm, and the second thickness is in the range from 1 to 4.5 nm, for example from 2 to 4 nm.

According to an embodiment, the gate region has a second length in the first direction, the first length being smaller than the second length.

According to an embodiment, the gate region extends above and on either side of the first channel region in the first direction.

According to a specific embodiment, the gate region is centered with respect to the first channel region.

According to an embodiment, a non-zero distance separates a side wall of the gate region and the second gate insulator portion, for example the distance being in the range from 70 to 100 nm, or from 80 to 90 nm.

According to an embodiment, the distance is greater than an overlap length of the lightly-doped drain region under the gate region.

According to an embodiment, the first epitaxial channel region is made of silicon.

According to another embodiment, the first epitaxial channel region is made of a silicon-germanium alloy.

According to an embodiment, the gate insulator is made of a silicon oxide, for example of silicon dioxide, and/or the semiconductor layer is made of silicon.

An embodiment provides an electronic device comprising at least one transistor such as described hereinabove.

An embodiment provides a radio frequency switch comprising at least one transistor such as described hereinabove.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows, in a longitudinal cross-section view, an example of an electronic device comprising a MOSFET transistor;

FIG. 2A shows, in a longitudinal cross-section view, an electronic device comprising a MOSFET transistor according to an embodiment;

FIG. 2B shows, in a top cross-section view, the electronic device of FIG. 2A;

FIG. 3A, FIG. 3B, FIG. 3C, FIG. 3D, and FIG. 3E are longitudinal cross-section views, partially and schematically illustrating successive steps of an example of a method of manufacturing a MOSFET transistor similar to the transistor of FIG. 2A; and

FIG. 4A and FIG. 4B show curves representing drain current values according to the gate voltage for a reference transistor and for a transistor according to an embodiment.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the steps of the MOSFET transistor manufacturing method have not all been described, as they can be carried out with current methods of microelectronics. Similarly, the details of MOSFET transistors have not all been described. Further, the applications that the described transistors may have not all been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

In the following description, a length corresponds to a dimension in a first lateral direction of a MOSFET transistor (direction X indicated in the drawings), corresponding to a direction parallel to the conduction direction of the transistor, a width corresponds to a dimension in a second lateral direction (direction Y indicated in the drawings), orthogonal to the first direction, and a thickness or depth corresponds to a dimension in a third direction perpendicular to the first and second directions (vertical direction Z indicated in the figures). Thus, the dimension, along the X direction, of a channel-forming region of the transistor is referred to as the transistor channel length, substantially corresponding to the distance between a source region and a drain region of the transistor.

In the following description, in order to make it lighter, a MOSFET may be designated as a transistor.

The transistors shown in the following description are, for example, N-channel MOS transistors (NMOS), that is, transistors having N-type doped source and drain regions, for example, doped with arsenic or phosphorus atoms, while the body region is P-type doped, for example doped with boron atoms.

As a variant, the transistors shown may be P-channel MOS transistors (PMOS), that is, transistors having P-type doped source and drain regions, for example doped with boron atoms, while the body region is N-type doped, for example doped with arsenic or phosphorus atoms.

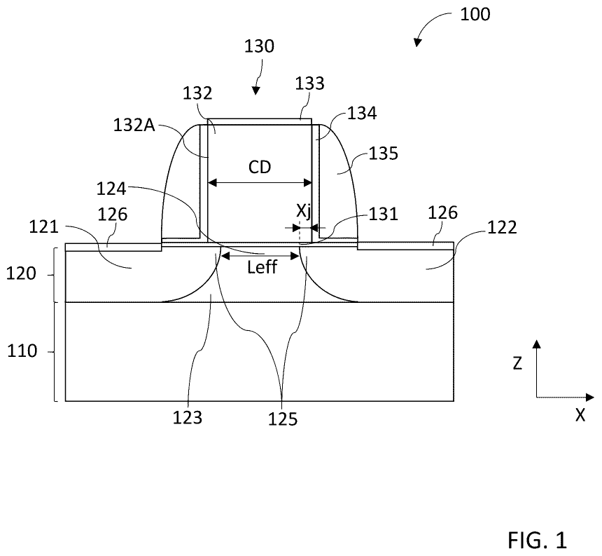

FIG. 1 shows, in a longitudinal cross-section view, an example of an electronic device comprising a MOSFET transistor 100.

MOSFET transistor 100 is formed inside and on top of a semiconductor layer 120. The electronic device comprises a buried insulator layer 110, under semiconductor layer 120. Layers 110 and 120 correspond, for example, to a stack of SOI (Semiconductor On Insulator) type, the electronic device then comprising a substrate in contact with and under buried insulator layer 110 (substrate not shown). Semiconductor layer 120 is, for example, on top of and in contact with buried insulator layer 110.

Semiconductor layer 120 is for example made of silicon, for example of single-crystal silicon, and buried insulator layer 110 is for example made of silicon dioxide (SiO₂).

Transistor 100 comprises a drain region 121 and a source region 122 formed in a region of semiconductor layer 120 called body region 123.

An upper portion 124 of body region 123, between drain region 121 and source region 122, forms the channel-forming region 124 of transistor 100, or “channel region”. As an example, drain region 121, source region 122, and body region 123 are flush with the upper surface of semiconductor layer 120.

Transistor 100 further comprises a gate structure 130 located above body region 123, preferably above channel region 124. Gate structure 130 generally comprises a conductive gate region 132, which for example comprises polysilicon and/or metal, and an insulator layer 131, called gate insulator, which insulates gate region 132 from semiconductor layer 120.

For example, gate region 132 has a length CD greater than or equal to 50 nm, or even greater than or equal to 100 nm.

For example, gate insulator 131 is made of silicon dioxide (SiO₂).

For example, gate insulator 131 has a thickness in the range from approximately 1 nm to 10 nm. The gate insulator may have a thickness in the range from approximately 1 to 4.5 nm for a transistor called GO1 (“Gate Oxide 1”), that is, a transistor having a gate insulator of small thickness, or a thickness of in the range from approximately 5 to 10 nm, or even from approximately 5 to 7.5 nm, for a transistor GO2 (“Gate Oxide 2”), that is, a transistor having a gate insulator of strong thickness.

As an example, in FIG. 1, gate insulator 131 is on top of and in contact with semiconductor layer 120 and gate region 132 is on top of and in contact with gate insulator 131.

Gate region 132 may be topped with a conductive contact layer 133, which may be made of silicide. The drain region and the source region may also each be topped with a conductive contact layer 126, which may be made of silicide, which for example enables to decrease the access resistance.

On either side of gate region 132, on portions of semiconductor layer 120 not covered with this gate region and on the side walls (flanks) of gate region 132, transistor 100 generally comprises a thin protective oxide layer 134, for example a SiO₂ layer. The thickness of thin oxide layer 134 is, for example, in the range from 2 to 10 nm, or even from 2 to 5 nm.

Further, transistor 100 comprises insulating spacers 135 which coat the flanks of gate region 132 covered by thin oxide layer 134 and which extend over the portions of semiconductor layer 120 covered by this thin oxide layer 134. Each insulating spacer 135 is, for example, made of a silicon nitride (SiN).

Extension regions 125, or LDD (Lightly Doped Drain) regions, having a doping slightly lighter than the doping of the drain and source regions, may be formed at each junction between channel region 124 and drain 121 and source 122 regions, for example to limit the lateral electric field in the MOS transistor.

LDD regions 125, and sometimes drain 121 and source 122 regions, generally exhibit an overlap under gate region 132. Indeed, during the doping operation to form LDD regions 125, or even to form the drain 121 and source 122 regions, the dopant may diffuse over a certain length under the gate region. This overlap is represented in FIG. 1 by an overlap length Xj between the side wall 132A of gate region 132 and the inner edge of LDD region 125 (this inner edge corresponds to the junction of LDD region 125 with channel region 124). This overlap decreases the effective length Leff of channel-forming region 124, which is substantially equal to the length CD of gate region 132 minus twice overlap length Xj. Further, this overlap may form a parasitic overlap capacitance between the gate region and the LDD regions, or even the drain and source regions, which can lead to a decrease in the transistor performance. FIG. 1 shows the same overlap length Xj on the side of drain region 121 as on the side of source region 122, but it is possible for this overlap not to be equal on both sides.

Although not shown in FIG. 1, an etch stop layer, for example made of SiN (or SiN 34), topped with a region called “PMD” (Pre-Metal Dielectric) made of a dielectric material which may be silicon dioxide (SiO₂), may be located on transistor 100, and contacts may cross the etch stop layer and the PMD region all the way to the drain, source, and gate regions of transistor 100, for example all the way to the conductive contact layers of these regions.

In certain applications, it is searched for a better control of overlap capacitances, which can be designated by the term “Miller capacitances”. It may be searched for the decrease of these capacitances, in particular to avoid too large a dispersion in the performance of MOSFET transistors. A solution to decrease Miller capacitances is to increase the gate insulator thickness. However, thereby, this may result, all other things being equal, in increasing in the threshold voltage of the transistor, and in degrading certain performances of the transistor, for example its switching speed.

The inventors provide a MOSFET transistor enabling to meet the above-described improvement needs, and to overcome all or part of the disadvantages of the above-described MOSFET transistors. In particular, the inventors provide a MOSFET transistor which enables to decrease the overlap capacitances, or Miller capacitances, without for all this degrading the transistor performance, in particular without increasing the threshold voltage of the transistor. It would be desirable to have such a MOSFET transistor without complicating the transistor manufacturing method. It would be advantageous for the embodiments not to require decreasing the effective length of the channel-forming region.

Embodiments of MOSFET transistor will be described below. The described embodiments are non-limiting and various variants will occur to those skilled in the art based on the indications of the present disclosure.

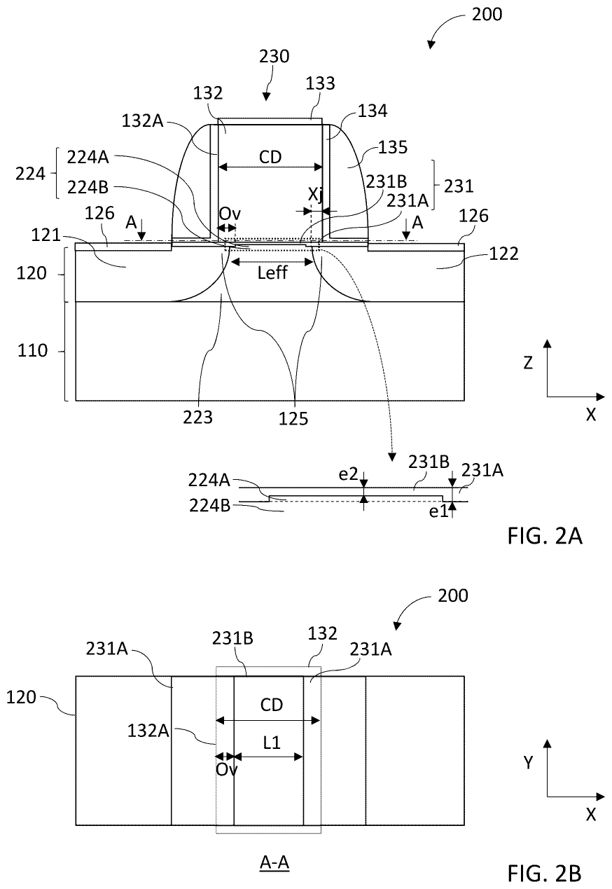

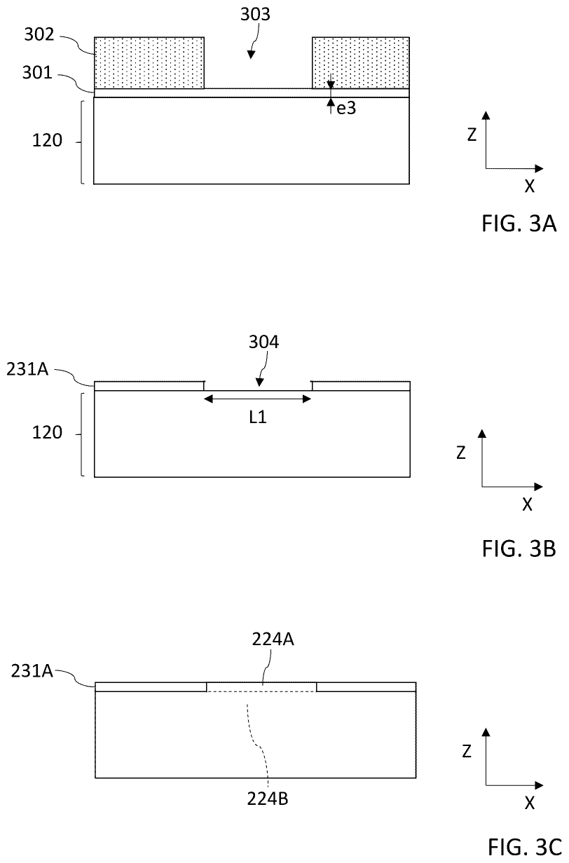

FIG. 2A shows, in a longitudinal cross-section view, an electronic device comprising a MOSFET 200 according to an embodiment. FIG. 2B shows, in a top cross-section view, the MOSFET transistor 200 of FIG. 2A. The cross-section view of FIG. 2B is obtained along the cross-section plane AA indicated in FIG. 2A.

The MOSFET transistor 200 of FIGS. 2A and 2B differs from the MOSFET transistor 100 of FIG. 1 mainly in that: channel region 224 comprises a first channel region 224A which is an epitaxial region, and a second channel region 224B in semiconductor layer 120, which second channel region may be similar to the channel region 124 of FIG. 1, the first channel region 224A being located between the second channel region 224B and gate structure 230; and the gate insulator 231 of gate structure 230 comprises first portions 231A on either side of the first channel region 224A, and a second portion 231B which is positioned on the first channel region 224A.

The second channel region 224B extends under the first channel region 224A and also partly under the first gate insulator portions 231A.

Gate insulator 231 may be made of a silicon oxide, for example of SiO₂.

The first portions 231A of gate insulator 231 have a first thickness e1, and the second portion 231B of gate insulator 231 has a second thickness e2 which is smaller than the first thickness e1.

For example, the first portions 231A are of GO2 type and the second portion 231B is of GO1 type.

For example, the first thickness e1 is in the range from 5 to 10 nm, or even from 6 to 9 nm, and the second thickness e2 is in the range from 1 to 4.5 nm, or even from 2 to 4 nm.

Preferably, the length L1 (first length) of the first channel region 224A, which substantially corresponds to the length of the second gate insulator portion 231B, is smaller than the length CD (second length) of gate region 132.

For example, length L1 is in the range from 1 to 2.5 μm, for example equal to approximately 1.8 μm.

The thickness of the first channel region 224A is preferably smaller than or equal to the first thickness e1. For example, the thickness of the first channel region 224A is in the range from 6 to 9 nm.

The first epitaxial channel region 224A may be made of silicon (Si). AS a variant, the first epitaxial channel region 234A may be made of a silicon-germanium (SiGe) alloy, enabling to have a stressed channel region 224, and to increase the charge mobility.

Preferably, gate region 132 is above, and overhangs on either side of, the first channel region 224A, or the second portion 231B, in the X direction, so that a non-zero distance Ov separates the side wall 132A of gate region 132 and the second gate insulator portion 231B. This distance Ov corresponds to a length in which gate region 132 is separated from semiconductor region 120, in particular from the LDD regions and from the drain and source regions, by the largest thickness (the first thickness e1) of the gate insulator, corresponding to the thickness of the first gate insulator portions 231A.

For example, gate region 132 is centered with respect to the first channel region 224A and/or to the second gate insulator portion 231B.

Preferably, distance Ov is greater than the overlap length Xj of LDD region 125, and/or of the drain 121 and source 122 regions, under gate region 132, so that this overlap occurs under the largest gate insulator thickness (thickness e1). Thus, the overlap capacitance can be decreased.

Further, due to a smaller gate insulator thickness (thickness e2) between gate region 132 and the first channel region 224A, the threshold voltage may be decreased.

It should be noted that to decrease the overlap capacitance, it is possible to decrease overlap distance Xj. A known solution is to form an offset spacer on the side walls of gate region 132 and on thin protection oxide layer 134, enabling to provide an offset during the forming of LDD regions 125, before forming insulating spacers 135 and the drain 121 and source 122 regions. Such an offset spacer forms a protective mask which continues the mask formed by gate region 132 and thin oxide layer 134 during the operation of doping of the LDD regions, to limit the dopant diffusion under the gate region. The embodiments may enable to advantageously dispense with the need for such offset spacers, particularly enabling to simplify the manufacturing method.

As an example, overlap distance Xj is in the range from 40 to 80 nm, for example equal to approximately 60 nm.

For example, distance Ov is in the range from 70 to 100 nm, for example from 80 to 90 nm, for example equal to approximately 85 nm.

FIGS. 2A and 2B show a same overlap length Xj on the side of drain region 121 and on the side of source region 122, but it is possible for this overlap length not to be equal on both sides. Similarly, FIGS. 2A and 2B show a same distance Ov on the side of drain region 121 and on the side of source region 122, but it is possible for this distance not to be equal on both sides.

The inventors have determined that the presence of a step in gate insulator 231, between each first portion 231A and second portion 231B, enables to modify the current lines and in particular to concentrate the current at the interface between the first channel region 224A and the second gate insulator portion 231B, which has a smaller thickness (thickness e2), favoring current conduction at this interface, and thus potentially to decrease the transistor threshold voltage. Further, as explained above, the overlap capacitance may be reduced due to a greater gate insulator thickness (thickness e1 of the first gate insulator portions 231A). Thus, the embodiments enable to decrease the overlap capacity without increasing the threshold voltage, or even while decreasing it.

The inventors have also determined that the embodiments could improve the reliability over time of the transistor, in particular by decreasing the charge carrier phenomenon.

Indeed, the presence of the step in gate insulator 231, particularly enabling to modify the current lines as discussed hereabove, enables to slow down charge carriers so that the latter end up in a limited area between each first gate insulator portion 231A and each LDD region 125. Thus, fewer charge carriers can accumulate between gate structure 230 and each LDD region.

The other characteristics of the MOSFET transistor 200 of FIGS. 2A and 2B, designated with the same references as those of FIG. 1, may be similar to those of the MOSFET transistor 100 of FIG. 1, and are not described again.

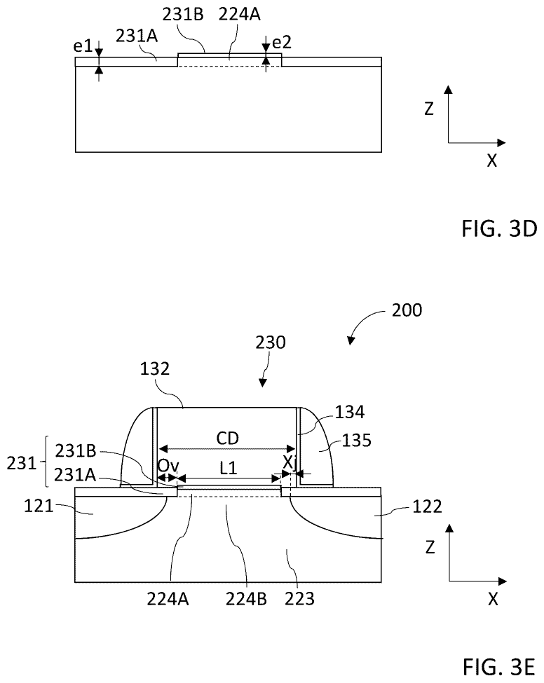

FIG. 3A, FIG. 3B, FIG. 3C, FIG. 3D, and FIG. 3E are longitudinal cross-sectional views, partially and schematically illustrating successive steps of an example of a method of manufacturing a MOSFET transistor similar to the transistor of FIG. 2A.

FIG. 3A shows an initial structure comprising a semiconductor layer 120. The initial structure may comprise a buried insulator layer in contact with and under semiconductor layer 120, or even a substrate in contact with and under the buried insulator layer (substrate and buried insulator layer not shown), corresponding for example to an SOI-type stack.

The structure of FIG. 3A further comprises a first insulator layer 301 on top of semiconductor layer 320. This first insulator layer 301 is intended to form the first gate insulator portions 231A, and has a third thickness e3, which may be smaller than or equal to the first thickness e1.

The first insulator layer 301 may be formed by oxidizing semiconductor layer 120. The first insulator layer 301 may be formed by oxidizing semiconductor layer 120 across an initial thickness greater than the third thickness e3, for example approximately 20 nm, and then by removing part of this thickness to obtain the third thickness e3. For example, semiconductor layer 120 is made of silicon, and the first insulator layer 301 is made of a silicon oxide, for example of SiO₂.

Further, an etch mask 302 is formed on the first insulator layer 301. Etch mask 302 comprises an opening 303, corresponding to the desired opening in the first insulator layer 301 at the next step.

FIG. 3B shows a structure obtained at the end of a step of etching of the first insulator layer 301 through etch mask 302. During this step, the first insulator layer 301 is etched from its upper surface, only a central portion of the first insulator layer 301 located under the opening 303 of etch mask 302 is removed, forming an opening 304 in the first insulator layer 301, and the portions of the first insulator layer 301 located under etch mask 302 remain, forming all or part of the first gate insulator portions 231A.

The etching is preferably a wet etching. For example, this etching step is carried out with hydrofluoric acid, for example, for a duration in the range from 150 to 400 seconds.

The etching stops at semiconductor layer 120.

Etch mask 302 is then removed.

There has been shown in FIG. 3B an embodiment in which the portions of the first insulator layer 301 remaining after the etching form the first gate insulator portions 231A, and in which the third thickness e3 is substantially equal to the first thickness e1, but other embodiments may be envisaged by those skilled in the art. For example, the forming of the second gate insulator portion 231B described hereafter may increase the thickness e3 of the second gate insulator portions 231A to obtain the first thickness e1.

FIG. 3C corresponds to a structure obtained at the end of the forming, by epitaxial growth, of a semiconductor layer, for example made of silicon, in the opening 304 of the first insulator layer 301, thus forming the first channel region 224A.

The second channel region 224B is intended to be formed under the first channel region 224A.

The thickness of the first epitaxial channel region 224A is, for example, substantially equal to the third thickness e3. In this case, the first channel region 224A may be flush with the first gate insulator portions 231A. As a variant, the thickness of the first epitaxial channel region 224A may be smaller than the third thickness e3, for example the first channel region 224A does not completely fill opening 304.

FIG. 3D shows a structure obtained at the end of the forming of a second insulator layer on the first channel region 224A, corresponding to the second gate insulator portion 231B, of thickness e2 (second thickness). The second thickness e2 is preferably smaller than the third thickness e3.

This second gate insulator portion 231B may be formed by oxidizing the first channel region 224A. For example, the first channel region 224A is made of silicon, and the second gate insulator portion 231B is made of a silicon oxide, for example of SiO₂. An oxidation may occur to a lesser extent, that is, generally less rapidly and thus across a thickness smaller than the second thickness e2, on the first gate insulator portions 231A. In this case, the thickness of the first gate insulator portions 231A may slightly increase during the oxidation to form the second gate insulator region 231B, so that the first thickness e1 is greater than the third thickness e3, and greater than the second thickness e2.

The second gate insulator portion 231B may be raised with respect to the level of the first portions 231A, as illustrated in FIG. 3D. As a variant, the second gate insulator portion 231B may be flush with the first portions 231A, as illustrated in FIG. 2A.

As a variant, the second gate insulator portion 231B may be formed by deposition of a second insulator layer on the second channel region 224A, and optionally also on the first gate insulator portions 231A.

For example, the third thickness e3 is in the range from 4.5 to 9.5 nm, the first thickness e1 is in the range from 5 to 10 nm, or even from 6 to 9 nm, and the second thickness e2 is in the range from 1 to 4.5 nm, or even from 2 to 4 nm.

FIG. 3E corresponds to a structure, similar to the transistor 200 of FIG. 2A, obtained at the end of standard steps of forming of gate region 132 on gate insulator 231, of protective oxide layers 134 on the flanks of gate region 132, of the LDD regions by doping of semiconductor layer 120 on either side of the gate region 132 covered with oxide layers 134, of insulating spacers 135 on oxide layers 134, and then of drain regions 121 and source regions 122 by doping of semiconductor layer 120 on either side of the gate region 132 covered with insulating spacers 135.

During the forming of gate structure 230, a stack of one or a plurality of layers of material(s) intended to form gate region 132 may be deposited on gate insulator 231, after which this stack is laterally etched to form gate region 132 according to the desired length CD of this gate region. This etching is preferably selected so that this length CD is greater than the length L1 of the first channel region 224A. Preferably, the etching of the stack is selected so that gate region 132 overhangs on either side of second gate insulator portion 231B in the X direction, by a non-zero distance Ov. For example, gate region 132 is centered with respect to the second portion 231B.

In FIG. 3E, there has been shown a length CD of gate region 132 greater than the length CD of FIG. 2A, distance Ov being substantially the same. This can be simply achieved by increasing opening 303 in etch mask 302, to increase the length of opening 304 in the first insulator layer 301. More generally, those skilled in the art will know how to modify the values of length CD and of distance Ov by simply adapting the manufacturing method.

For an NMOS transistor, the doping of the source and drain regions, and of the LDD regions, may use N-type dopants such as arsenic (As) or phosphorus (P). For a PMOS transistor, the doping of the source and drain regions, and of the LDD regions, may use P-type dopants such as boron (B).

Thus, the manufacturing of a MOSFET transistor according to the embodiments may be performed by implementing a standard MOSFET transistor manufacturing method.

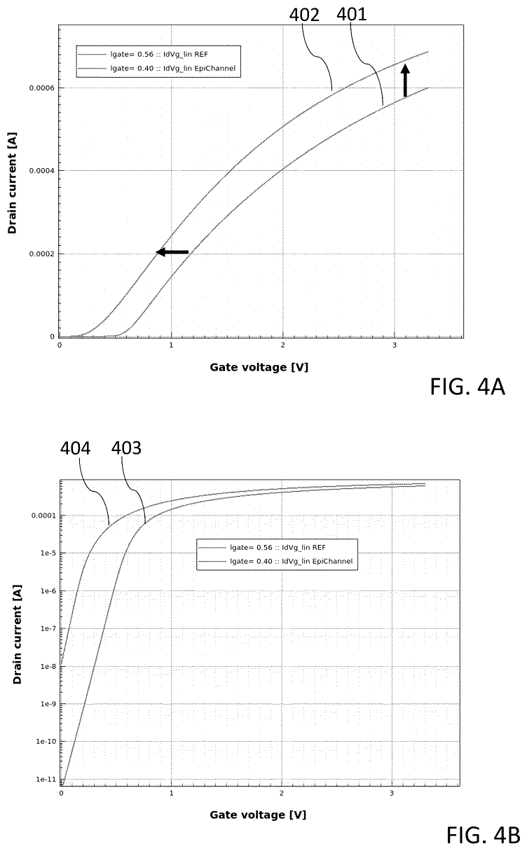

FIG. 4A and FIG. 4B show curves representing drain current values according to the gate voltage for a reference transistor, similar to the transistor in FIG. 1, and for a transistor according to an embodiment, similar to the transistor of FIGS. 2A and 2B. The manufacturing characteristics of the reference transistor and of the transistor according to an embodiment are similar, except for the gate insulator and the epitaxial channel region, in particular lengths CD and Leff and the doping are similar.

Curves 401 and 403 correspond to the reference transistor. Curves 402 and 404 correspond to the transistor of FIGS. 2A and 2B.

In FIG. 4A, current values are at a decimal scale, while in FIG. 4B, current values are at a logarithmic scale.

There appears from these curves that the embodiments enable to decrease the threshold voltage VT of the transistor, which has been represented by a horizontal arrow in FIG. 4A. They also enable to increase the saturation current, which has been represented by a vertical arrow in FIG. 4A. Thus, this may increase the transistor speed, for example the switching speed for applications such as the switching of radio frequency (RF) signals.

A transistor according to an embodiment may be embedded in an electronic device, which may further comprise one or a plurality of reference transistors, that is, with no stepped gate insulator and with no epitaxial channel region under the step.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A transistor comprising:
a drain region and a source region disposed in a semiconductor layer;
a channel-forming region extending in a first direction between the drain region and the source region, and
a gate structure disposed over the channel-forming region and comprising a gate insulator topped with a gate region insulated from the channel-forming region by the gate insulator;
the channel-forming region comprising
a first channel region having a first length in the first direction and being an epitaxial region, and
a second channel region in the semiconductor layer, the first channel region being between the second channel region and the gate structure; and
the gate insulator comprising first portions having a first thickness on the second channel region on either side of the first channel region, and a second portion of a second thickness over the first channel region, the second thickness being smaller than the first thickness.

2. The transistor according to claim 1, wherein the second portion is positioned between the first portions in the first direction.

3. The transistor according to claim 1, further comprising a lightly-doped drain region in the semiconductor layer, between the second channel region and each of the drain and source regions.

4. The transistor according to claim 1, wherein the first thickness is in a range from 5 to 10 nm, and the second thickness is in a range from 1 to 4.5 nm.

5. The transistor according to claim 1, wherein the gate region has a second length in the first direction, the first length being smaller than the second length.

6. The transistor according to claim 1, wherein the gate region extends over and on either side of the first channel region in the first direction.

7. The transistor according to claim 1, wherein an overlap distance separates a side wall of the gate region and a sidewall of the first portions of the gate insulator.

8. The transistor according to claim 7, further comprising a lightly-doped drain region in the semiconductor layer, between the second channel region and each of the drain and source regions, wherein the overlap distance is greater than an overlap length of the lightly-doped drain region under the gate region.

9. The transistor according to claim 1, wherein the first channel region is made of silicon or of a silicon-germanium alloy.

10. The transistor according to claim 1, wherein the gate insulator comprises a layer of silicon oxide, and the semiconductor layer comprises a layer of silicon.

11. An electronic device comprising at least one transistor according to claim 1.

12. A radio-frequency switch comprising at least one transistor according to claim 1.

13. A method of manufacturing a transistor, the method comprising:
forming a first insulator layer having a third thickness on a semiconductor layer;
forming an opening in the first insulator layer, the opening having a first length in a first direction;
forming, by epitaxy in the opening, a first channel region of a channel-forming region;
forming a second insulator layer having a second thickness over the first channel region;
portions of the first insulator layer that remain on either side of the opening forming first portions of a gate insulator, the first portions having a first thickness greater than or equal to the third thickness, and greater than the second thickness, and a portion of the second insulator layer directly over the first channel region forming a second portion of the gate insulator;
forming a gate region on the gate insulator; and
forming a drain region and a source region in the semiconductor layer, a second channel region of the channel-forming region extending in the first direction between the drain region and the source region.

14. The method according to claim 13, further comprising forming, in the semiconductor layer, a lightly-doped drain region between the second channel region and each of the drain and source regions.

15. The method according to claim 13, wherein forming the opening comprises etching the first insulator layer throughout the third thickness and along the first length in the first direction, the etching stopping at the semiconductor layer.

16. The method according to claim 13, wherein the first thickness is equal to the third thickness.

17. A method of manufacturing a transistor, the method comprising:
forming a first insulator layer over a semiconductor layer;
patterning the first insulator layer to form an opening in the first insulator layer and remaining portions, the opening having a first length in a first direction;
forming, by epitaxy in the opening, a first channel region of a channel-forming region;
forming a second insulator layer over the first channel region; the remaining portions of the first insulator layer forming first portions of a gate insulator, the second insulator layer being thinner than the remaining portions, and the portion of the second insulator layer formed over the first channel region forming a second portion of the gate insulator;
forming a gate region on the gate insulator; and
forming a drain region and a source region in the semiconductor layer, a second channel region of the channel-forming region extending in the first direction between the drain region and the source region.

18. The method according to claim 17, further comprising forming, in the semiconductor layer, a lightly-doped drain region between the second channel region and each of the drain and source regions.

19. The method according to claim 17, wherein the first channel region is made of a silicon-germanium alloy.

20. The method according to claim 17, wherein the gate region has a second length in the first direction, the first length being smaller than the second length.
